(19) United States
(12) Patent Application Publication
(10) Pub. No.: US 2022/0201890 A1
(43) Pub. Date: Jun. 23, 2022

(54) Power Module

(71) Applicant: ZF Friedrichshafen AG, Friedrichshafen (DE)

(72) Inventors: Wei Liu, Friedrichshafen (DE); Mitsutoshi Muraoka, Friedrichshafen (DE)

(21) Appl. No.: 17/557,711

(22) Filed: Dec. 21, 2021

(30) Foreign Application Priority Data
Dec. 22, 2020 (DE) 10 2020 216 477.0

(51) Int. Cl. H05K 7/20; H01F 27/36

(52) U.S. Cl. CPC H05K 7/209; H01F 27/36

(57) ABSTRACT

A power module includes a case defining an accommodation space, and a baseplate having a circuit pattern, the baseplate being coupled to the case such that the circuit pattern is within the accommodation space. The power module further includes a plurality of power elements on the circuit pattern and electrically connected to the circuit pattern, and a shielding member above the power elements to shield electromagnetic interference of the power elements, with the shielding member being grounded. Moreover, the power module includes an encapsulating material within the accommodation space, with the encapsulating material covering at least the circuit pattern and the power elements. Additionally, the power module includes a cooling member coupled to the baseplate on a side of the baseplate further from the case.

### CROSS-REFERENCE TO RELATED APPLICATION

The present application is related and has right of priority to German Patent Application No. 10 2020 216 477.0 filed on Dec. 22, 2020, the entirety of which is incorporated by reference for all purposes.

### FIELD OF THE INVENTION

The invention relates generally to a power module, in particular to a power module with an inner shielding member.

### BACKGROUND OF THE INVENTION

An inverter is usually used to convert direct current (‘DC’) to alternating current (‘AC’) to power a three-phase load, such as an electric motor. An inverter contains a power module 1 having power elements 12, such as insulated-gate bipolar transistors (IGBTs), metal-oxide-semiconductor field-effect transistors (MOSFETs) and Silicon Carbide (SiC) devices, and a drive board 2 driving these power elements 12, as shown in FIG. 1. In particular, the power module 1 has a carrier 11 for carrying power elements 12 and pins or terminals 13. The carrier 11 is part of a direct bonded copper (DBC) or an insulated metal substrate (IMS). Resin 14 having a low dielectric constant and low stress is used to encapsulate the power module 1. The drive board 2 includes a circuit board 20 with electronic components 21, 22 (such as driving chips, resistances, capacitors, diodes, triodes, etc.) on both sides. The pins transmit driving signals for switching on and off the power elements 12 and sensor signals, such as temperature signals. The terminals 13 for example include connectors, such as AC connectors and DC connectors which are coupled to other electric components. Conventionally, the power module 1 and the drive board 2 are spaced apart by a relatively large distance H which leads to large inductance of gate loops, which in turn generates non-negligible noises.

To reduce the inductance of gate loops, the drive board 2 should be arranged closer to the power module 1. However, when the drive board 2 is closer to the power module 1, the power module 1 may interfere with the drive board 2 and cause malfunction of the power elements, namely an Electro Magnetic Compatibility (EMC) problem occurs.

Inserting an electrical shielding member 3 (such as a copper sheet) between the power module 1 and the drive board 2, as shown in FIG. 2, sometimes solves the EMC problem. However, as chips and/or electronic components 22, such as resistances, capacitors, etc., are provided on the rear surface of the circuit board 20, the insertion of the electrical shielding member 3 may cause a short circuit. In order to avoid a short circuit, there must be a space between the power module 1 and the drive board 2. However, the space between the power module 1 and drive board 2 again causes the large inductance of gate loops, and thus the noise problem is still not fixed.

### SUMMARY OF THE INVENTION

In order to balance the noise problem and the EMC problem, a power module with an inner shielding member is provided. The power module includes a case having an accommodation space and a baseplate with a circuit pattern provided on it, wherein the baseplate is jointed to the case such that the circuit pattern is accommodated in the accommodation space. The power module further includes a plurality of power elements provided on the circuit pattern and electrically connected to the circuit pattern, a grounded shielding member provided above the power elements and shielding the electromagnetic interference of the power elements, encapsulating material provided in the accommodation space, the encapsulating material covering at least the circuit pattern and the power elements, and a cover coupled to the case on a side of the case adjacent to the encapsulating material, where the cover and the baseplate enclose the accommodation space. Additionally, the power module includes a cooling member jointed to the baseplate on a side of the baseplate away from the case. By providing the shielding member inside the power module, electro-magnetic interference of the power elements is shielded effectively.

In a preferred embodiment, a portion of the accommodation space between the baseplate and the shielding member is filled with the encapsulating material. Typically, the encapsulating material, which is a gel, protects the power elements and the circuit pattern from dust and is used as a shock absorption layer.

In another preferred embodiment, a portion of the accommodation space between the shielding member and the cover is filled with the encapsulating material.

In another preferred embodiment, the case further has a supporting member for supporting the shielding member.

In another preferred embodiment, the supporting member is a flange provided on the inner sidewall of the case. The flange is preferably formed integrally with the case.

In another preferred embodiment, the shielding member is grounded to a ground of the cooling member by a conductive fastener or a wire via a metal layer in the case.

In another preferred embodiment, the power module further has a plurality of external connectors electrically connected to the circuit pattern, a plurality of through holes are respectively provided through the shielding member and the cover for the external connectors to pass through, the external connectors are electrically isolated from the shielding member.

In another preferred embodiment, the shielding member is a copper sheet or an aluminum sheet.

In another preferred embodiment, the circuit pattern is integrated into a DBC or an IMS provided on the baseplate.

According to another aspect of the invention, a power module is disclosed. The power module includes a case having an accommodation space and a baseplate with a circuit pattern provided on it, where the baseplate is jointed or coupled to the case such that the circuit pattern is accommodated in the accommodation space. The power module further includes a plurality of power elements provided on the circuit pattern and electrically connected to the circuit pattern, a grounded shielding member provided above the power elements to shield electromagnetic interference of the power elements, and an encapsulating material provided in the accommodation space, the encapsulating material covering at least the circuit pattern and the power elements. Additionally, the power module includes a cooling member jointed or coupled to the baseplate on a side of the baseplate away or further from the case, where the shielding member is coupled to the case on a side of the case adjacent to the encapsulating material, and where the shielding member and the baseplate enclose the accommodation space. In this design, the shielding member is used as a cover to make the power module as compact as possible.

In another preferred embodiment, the surface of the shielding member away or further from the baseplate is insulated to prevent a short circuit when a drive board is provided on the power module.

In another preferred embodiment, a patterned insulated layer is provided on the surface of the shielding member away or further from the baseplate. When the power module and a drive board are assembled, the patterned insulated layer corresponds to an area on the rear surface of the drive board where electronic elements are provided. The drive board is provided as close as possible to the power module since electronic elements are insulated to the power module due to the patterned insulated layer, thus the inductance of the gate loop is substantially decreased.

In another preferred embodiment, the accommodation space is filled with the encapsulating material. Typically, the encapsulating material, which is a gel, protects the power elements and the circuit pattern from dust and is used as a shock absorption layer.

In another preferred embodiment, the case further has a supporting member for supporting the shielding member.

In another preferred embodiment, the supporting member is a flange provided on the inner sidewall of the case. The flange is preferably formed integrally with the case.

In another preferred embodiment, the shielding member is grounded to a ground of the cooling member by a conductive fastener or a wire via a metal layer in the case.

In another preferred embodiment, the power module further has a plurality of external connectors electrically connected to the circuit pattern, a plurality of through holes are provided on the shielding member for the external connectors to pass through, the external connectors are electrically isolated from the shielding member.

In another preferred embodiment, the circuit pattern is integrated into a DBC or an IMS provided on the baseplate.

Other aspects and advantages of the embodiments will become apparent from the following detailed description taken in conjunction with the accompanying drawings which illustrate, by way of example, the principles of the described embodiments.

### BRIEF DESCRIPTION OF THE DRAWINGS

The described embodiments and the advantages thereof may best be understood by reference to the following description taken in conjunction with the accompanying drawings. These drawings in no way limit any changes in form and detail that may be made to the described embodiments by on skilled in the art without departing from the spirit and scope of the described embodiments.

FIG. 1 illustrates a cross sectional view of a conventional inverter having a power module and a drive board;

FIG. 2 illustrates a cross sectional view of another conventional inverter with a shielding member;

FIG. 3 is a cross-sectional view of a power module in accordance with a preferred embodiment of the invention;

FIG. 4 is a cross-sectional view of a power module in accordance with another preferred embodiment of the invention;

FIG. 5 is a perspective view of a power module in 3-phase application;

FIG. 6 is another perspective view of the power module shown in FIG. 5; and

FIG. 7 is a cross-sectional view of a power module in accordance with another preferred embodiment of the invention, wherein the cover is omitted.

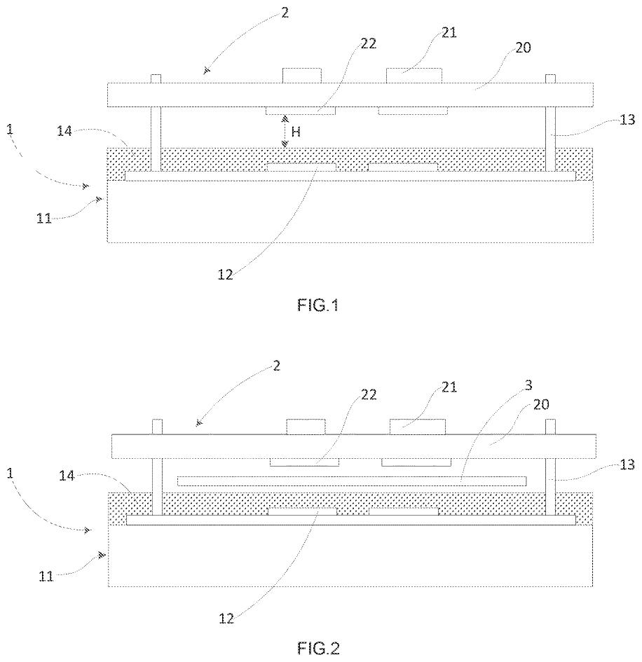

### DETAILED DESCRIPTION

Reference will now be made to embodiments of the invention, one or more examples of which are shown in the drawings. Each embodiment is provided by way of explanation of the invention, and not as a limitation of the invention. For example, features illustrated or described as part of one embodiment can be combined with another embodiment to yield still another embodiment. It is intended that the present invention include these and other modifications and variations to the embodiments described herein.

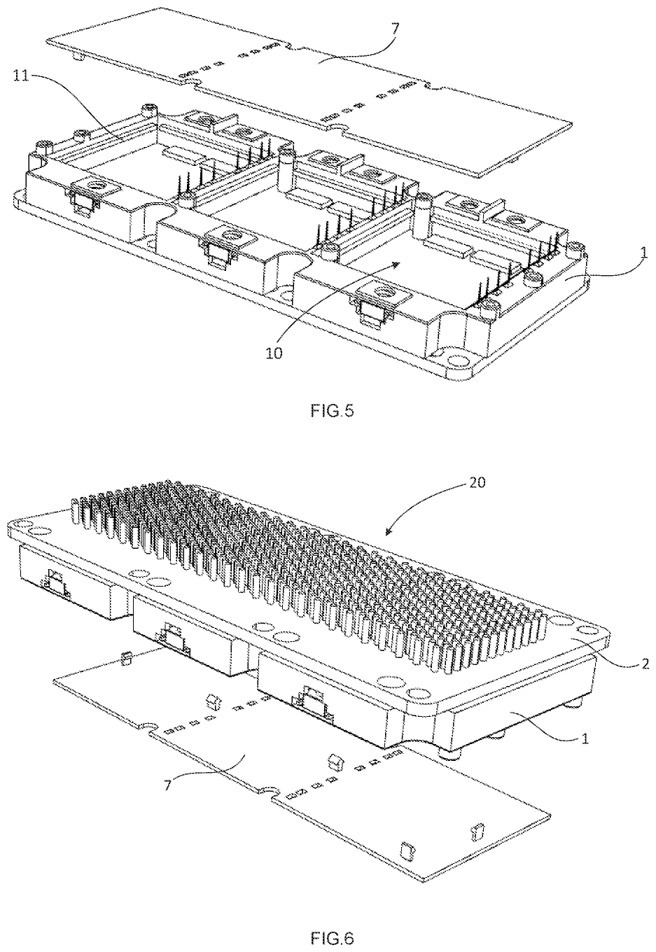

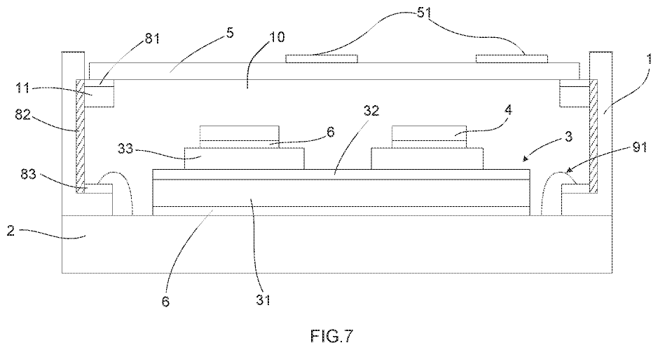

Referring now to the drawings, embodiments of the invention are described in detail. A power module with an inner shielding member according to a first embodiment is described in detail with reference to FIGS. 3-6. Referring to FIG. 3 and FIGS. 5-6, the power module has a case 1 defining an accommodation space 10, a baseplate 2 jointed or coupled to the case 1, a plurality of power elements 4, a grounded shielding member 5 for shielding the electromagnetic interference of the power elements 4, a cover 7 (see in FIGS. 5-6), a cooling member 20 (FIG. 6) and encapsulating material (not shown) filling the accommodation space.

The case 1 has a frame structure defining the accommodation space 10, wherein one side of the case 1 is jointed to the baseplate 2, the other side of the case 1 is coupled with the cover 7, thus the accommodation space 10 is enclosed. The baseplate 2 becomes the bottom plate of the power module, supporting electronic components including the power elements 4. Metals having excellent thermal conductivity, for example, aluminum and aluminum alloy, or copper and copper alloy, may be used for the baseplate 2. The cooling member 20 with a Pin-Fin structure is jointed to the baseplate 2. In one embodiment, the cooling member 20 is made of the same material as the baseplate 2.

In the embodiment shown in FIG. 3, a DBC (direct bonded copper) 3 is provided on the baseplate 2 to provide an electrical connection between the power elements 4 and pins and terminals (so called external connectors, in some applications, the pins and the terminals (not shown) are electrically connected to the power elements). The DBC 3 includes, from the bottom to the top, a copper layer 31, a ceramic layer 32, and a circuit pattern 33. Jointing material 6, which is typically solder, is used to join or couple the power elements 4 and the circuit pattern 33, as well as the DBC 3 and the baseplate 2. However, jointing material is not limited to solder. As an alternative to solder, for example, conductive adhesive is applied. The pins transmitting sensor signals and driving signals and terminals (such as AC and DC connectors) are provided either on the DBC or on the case 1.

The power module further has a grounded shielding member 5 (FIG. 3) for shielding the electromagnetic interference of the power elements 4. The shielding member 5 is a copper sheet covering the power elements 4 such that the electromagnetic interference of the power elements 4 is sheltered by the shielding member 5. By placing the shielding member 5 inside the power module, a drive board driving the power elements of the power module is placed as close to the power module as possible, and therefore the noise caused by the inductance of gate loop is largely decreased as the distance between the power module and the drive board is reduced.

In order to place the shielding member 5, the case 1 is provided with a supporting member, such as a flange 11 provided on the inner sidewall of the case 1. The flange 11 is preferably formed integrally with the case 1 and the upper surface of the flange 11 is covered by a metal layer segment 81. As shown in FIG. 3, the shielding member 5 is placed on the metal layer segment 81 of the flange 11. On the side of the case 1 adjacent to the baseplate 2, a second flange is provided on the inner sidewall of the case 1 and another metal layer segment 83 is formed on the upper surface of the second flange. In addition, a vertical metal layer segment 82, which connects the metal layer segments 81, 83, is formed in the sidewall of the case 1. Using the metal layer segments 81,82, 83 (forming a ‘C’ shape metal layer) and a wire 91 connecting the metal layer segment 83 to the baseplate 2, the shielding member 5 is supported inside the accommodation space 10 and is grounded.

In the embodiment that the pins and the terminals are provided on the DBC, a plurality of through holes are respectively provided through or defined in the shielding member 5 and the cover 7 for the pins and the terminals to pass through, and the pins and the terminals are electrically isolated from the shielding member 5.

By providing encapsulating material (not shown), such as gel, into a portion of the accommodation space 10 between the baseplate 2 and the shielding member 5, the power elements 4 and the circuit pattern 33 are protected from dust and vibrations. Preferably, the accommodation space is fully filled with encapsulating material.

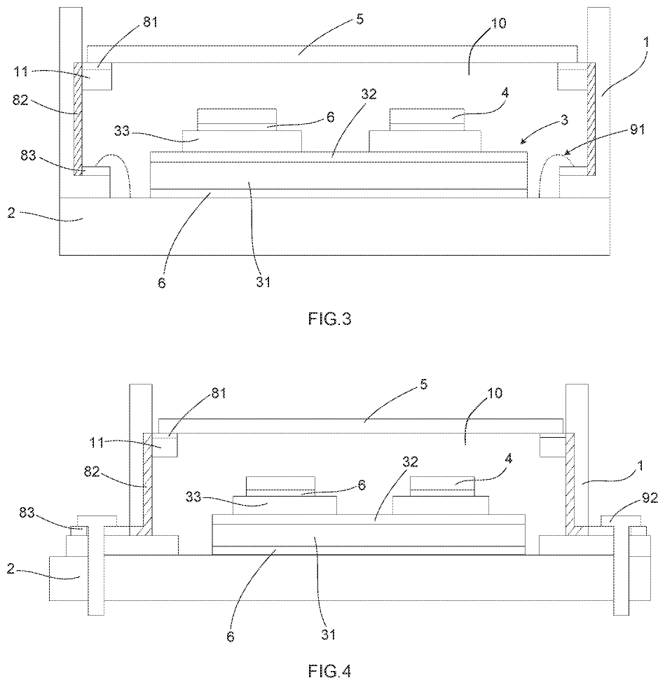

Now refer to FIG. 4, in another embodiment, the shielding member 5 is grounded and the case 1 is fastened to the baseplate 2 by a ‘Z’ shape metal layer and a conductive fastener, such as a bolt 92.

In another preferred embodiment, as shown in FIG. 7, the cover 7 is omitted. The shielding member 5 is coupled to the case 1 on the side of the case 1 adjacent to the encapsulating material (not shown), such that the shielding member 5 and the baseplate 2 enclose the accommodation space 10. The shielding member 5 functions as a cover as well, and therefore the power module is made more compact. From the standpoint of insulation between the power module and a drive board driving power elements in the power module, the surface of the shielding member 5 away from the baseplate (the surface facing the drive board) is insulated since electric components are provided on both sides of the drive board. In an alternative embodiment, a patterned insulated layer 51, for example a patterned insulated tape, is provided on the surface of the shielding member 5 away from the baseplate 2.

In this inner shielding member design, the drive board is placed as close to the power module as possible, and the inductance of gate loop is reduced significantly. Thus, the noise caused by the inductance of gate loop is negligible. Meanwhile, with the help of the shielding member 5 inside the power module, the EMC problem is well contained even if the drive board is very close to the power module, or even contacts the power module. Hence, the contradiction between the noise problem and the EMC problem is compromised.

A number of alternative structural elements and processing steps have been suggested for the preferred embodiment. Thus, while the invention has been described with reference to specific embodiments, the description is illustrative of the invention and is not to be construed as limiting the invention. Various modifications and applications may occur to those skilled in the art without departing from the true spirit and scope of the invention as defined by the appended claims.

Modifications and variations can be made to the embodiments illustrated or described herein without departing from the scope and spirit of the invention as set forth in the appended claims. In the claims, reference characters corresponding to elements recited in the detailed description and the drawings may be recited. Such reference characters are enclosed within parentheses and are provided as an aid for reference to example embodiments described in the detailed description and the drawings. Such reference characters are provided for convenience only and have no effect on the scope of the claims. In particular, such reference characters are not intended to limit the claims to the particular example embodiments described in the detailed description and the drawings.

1-16: (canceled)

17. A power module, comprising:
a case defining an accommodation space;
a baseplate having a circuit pattern, the baseplate being coupled to the case such that the circuit pattern is within the accommodation space;
a plurality of power elements on the circuit pattern and electrically connected to the circuit pattern;
a shielding member above the power elements to shield electromagnetic interference of the power elements, the shielding member being grounded;
an encapsulating material within the accommodation space, the encapsulating material covering at least the circuit pattern and the power elements;
a cover coupled to the case on a side of the case adjacent to the encapsulating material such that the cover and the baseplate enclose the accommodation space; and
a cooling member coupled to the baseplate on a side of the baseplate further from the case.

18. The power module of claim 17, wherein a portion of the accommodation space between the baseplate and the shielding member is filled with the encapsulating material.

19. The power module of claim 17, wherein a portion of the accommodation space between the shielding member and the cover is filled with the encapsulating material.

20. The power module of claim 17, wherein the case further comprises a supporting member for supporting the shielding member.

21. The power module as claimed in claim 20, wherein the supporting member is a flange on an inner sidewall of the case.

22. The power module of claim 17, wherein the shielding member is grounded to a ground of the cooling member by a conductive fastener or a wire via a metal layer in the case.

23. The power module of claim 17, further comprising a plurality of external connectors electrically connected to the circuit pattern,
wherein a plurality of through holes are defined through the shielding member and the cover for the external connectors to pass through, and
wherein the external connectors are electrically isolated from the shielding member.

24. The power module of claim 17, wherein the circuit pattern is integrated into a direct bonded copper (DBC) or an insulated metal substrate (IMS) on the baseplate.

25. A power module, comprising:
a case defining an accommodation space;
a baseplate having a circuit pattern, the baseplate being coupled to the case such that the circuit pattern is within the accommodation space;
a plurality of power elements on the circuit pattern and electrically connected to the circuit pattern;
a shielding member above the power elements to shield electromagnetic interference of the power elements, the shielding member being grounded;
an encapsulating material within the accommodation space, the encapsulating material covering at least the circuit pattern and the power elements; and
a cooling member coupled to the baseplate on a side of the baseplate further from the case,
wherein the shielding member is coupled to the case on a side of the case adjacent to the encapsulating material such that the shielding member and the baseplate enclose the accommodation space.

26. The power module of claim 25, wherein a surface of the shielding member further from the baseplate is insulated.

27. The power module of claim 25, wherein a patterned insulated layer is on a surface of the shielding member further from the baseplate.

28. The power module of claim 25, wherein the case further comprises a supporting member for supporting the shielding member.

29. The power module as claimed in claim 28, wherein the supporting member is a flange on an inner sidewall of the case.

30. The power module of claim 25, wherein the shielding member is grounded to a ground of the cooling member by a conductive fastener or a wire via a metal layer in the case.

31. The power module of claim 25, further comprising a plurality of external connectors electrically connected to the circuit pattern,
wherein a plurality of through holes are defined through the shielding member for the external connectors to pass through, and
wherein the external connectors are electrically isolated from the shielding member.

32. The power module of claim 25, wherein the circuit pattern is integrated into a direct bonded copper (DBC) or an insulated metal substrate (IMS) on the baseplate.
